(19) United States
(12) Patent Application Publication
(10) Pub. No.: US 2023/0223423 A1
(43) Pub. Date: Jul. 13, 2023

(54) DISPLAY DEVICE AND METHOD OF MANUFACTURING THE SAME

(71) Applicant: Samsung Display Co., LTD., Yongin-si (KR)

(72) Inventors: Hyun Sup LEE, Yongin-si (KR); Kang Young LEE, Yongin-si (KR); Moon Won CHANG, Yongin-si (KR)

(73) Assignee: Samsung Display Co., LTD., Yongin-si (KR)

(21) Appl. No.: 18/076,493

(22) Filed: Dec. 7, 2022

(30) Foreign Application Priority Data
Jan. 7, 2022 (KR) 10-2022-0002891

(51) Int. Cl. H01L 27/15; H01L 33/00; H01L 33/24; H01L 33/38; H01L 33/50

(52) U.S. Cl. CPC H01L 27/156; H01L 33/0093; H01L 33/24; H01L 33/38; H01L 33/50; H01L 2933/0016

(57) ABSTRACT

A display device includes light emitting elements each including a first area and a second area having different diameters, and a base layer surrounding the first area of the light emitting elements and contacting the first area of each of the light emitting elements. The second area of each of the light emitting elements protrudes from a first surface of the base layer.

### CROSS-REFERENCE TO RELATED APPLICATION(S)

The application claims priority to and benefits of Korean Patent Application No. 10-2022-0002891 under 35 U.S.C. §119, filed in the Korean Intellectual Property Office on Jan. 7, 2022, the entire contents of which are incorporated herein by reference.

### BACKGROUND

### 1. Technical Field

The disclosure relates to a display device of high-resolution and a method of manufacturing the same.

### 2. Description of the Related Art

The importance of display devices has been emphasized because of the increasing developments of information technologies. Thus, the display devices have grown in popularity.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device of high-resolution.

Embodiments also provide a method of manufacturing the display device.

However, embodiments of the disclosure are not limited to those set forth herein. The above and other embodiments will become more apparent to those skilled in the art to which the disclosure pertains by referencing the detailed description of the disclosure given below.

In order to achieve the object of the disclosure, a display device according to an embodiment of the disclosure may include light emitting elements including a first area and a second area each having different diameters; and a base layer surrounding the first area of the light emitting elements and contacting the first area of each of the light emitting elements. The second area of each of the light emitting elements may protrude from a first surface of the base layer.

A diameter of the first area of each of the light emitting elements may be greater than a diameter of the second area of each of the light emitting elements.

Each of the light emitting elements may include a first semiconductor layer, a second semiconductor layer, and an active layer disposed between the first semiconductor layer and the second semiconductor layer.

The display device may further include a first electrode disposed on the first area of each of the light emitting elements.

The base layer may include an opening exposing an end of the first area of each of the light emitting elements.

The first electrode may electrically contact the end of the first area of each of the light emitting elements through the opening of the base layer.

The first electrode may be disposed directly on a second surface of the base layer.

The display device may further include a second electrode disposed on the second area of each of the light emitting elements.

The second electrode may be disposed directly on the first surface of the base layer.

A thickness of the base layer may be greater than a thickness of the first area of each of the light emitting elements.

A thickness of the base layer may be substantially equal to a thickness of the first area of each of the light emitting elements.

The light emitting elements may include a first light emitting element emitting light of a first color; a second light emitting element emitting light of a second color; and a third light emitting element emitting light of a third color.

The display device may further include a color conversion layer disposed on the light emitting elements.

The display device may further include a color filter layer disposed on the color conversion layer.

In order to achieve the object of the disclosure, a method of manufacturing a display device according to an embodiment of the disclosure may each include preparing light emitting elements including a first area and a second area having different diameters from each other; fixing the second area of each of the light emitting elements to a wafer; forming a base layer on the first area of each of the light emitting elements protruding from the wafer; and separating the base layer and the second area of each of the light emitting elements from the wafer.

A diameter of the first area of each of the light emitting elements may be greater than a diameter of the second area of each of the light emitting elements.

A thickness of the base layer may be greater than a thickness of the first area of each of the light emitting elements.

The method may further include etching the base layer to form an opening exposing an end of the first area of each of the light emitting elements.

The method may further include forming a first electrode on the end of the first area of each of the light emitting elements exposed by the opening of the base layer.

The method may further include forming a second electrode on the second area of each of the light emitting elements separated from the wafer and exposed.

Details of other embodiments are included in the detailed description and drawings.

### BRIEF DESCRIPTION OF THE DRAWINGS

An additional appreciation according to the embodiments of the inventive concepts will become more apparent by describing in detail the embodiments thereof with reference to the accompanying drawings, wherein:

FIG. 1 is a schematic perspective view illustrating a light emitting element according to an embodiment;

FIG. 2 is a schematic cross-sectional view illustrating the light emitting element according to an embodiment;

FIG. 3 is a schematic perspective view illustrating a light emitting element according to another embodiment;

FIG. 4 is a schematic cross-sectional view illustrating the light emitting element according to another embodiment;

FIG. 5 is a schematic plan view illustrating a display device according to an embodiment;

FIG. 6 is a schematic diagram of an equivalent circuit illustrating a pixel according to an embodiment;

FIGS. 7 to 10 are schematic cross-sectional views of pixels according to an embodiment;

FIG. 11 is a schematic cross-sectional view illustrating a pixel according to another embodiment; and

FIGS. 12 to 16 are schematic cross-sectional views illustrating a method of manufacturing a display device according to an embodiment in each process step.

### DETAILED DESCRIPTION OF THE EMBODIMENTS

In the following description, for the purpose of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive and do not limit the disclosure. For example, specific shapes, configurations, and characteristics of an embodiment may be used or implemented in another embodiment.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the term “comprises,” “comprising,” “includes,” and/or “including,” when used in this specification, specify the presence of stated features, integers, components, steps, operations, elements, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some example embodiments may be physically separated into two or more interacting and discrete blocks, units, and/or modules without departing from the scope of the inventive concepts. Further, the blocks, units, and/or modules of some example embodiments may be physically combined into more complex blocks, units, and/or modules without departing from the scope of the inventive concepts.

In addition, the term “connection” or “connected” may refer to physical, electrical, and/or fluid connection, with or without intervening elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. Like reference numerals refer to like elements throughout the disclosure.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

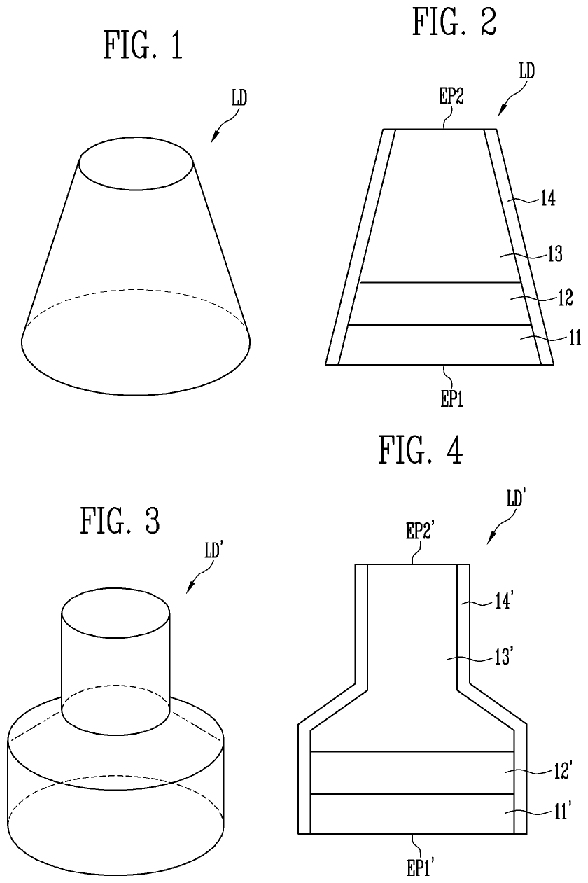

FIG. 1 is a schematic perspective view illustrating a light emitting element according to an embodiment. FIG. 2 is a schematic cross-sectional view illustrating the light emitting element according to an embodiment.

Referring to FIGS. 1 and 2, a light emitting element LD may include a first semiconductor layer 11, an active layer 12, and/or a second semiconductor layer 13.

The light emitting element LD may have a first end EP1 and a second end EP2. One of the first and second semiconductor layers 11 and 13 may be disposed at the first end EP1 of the light emitting element LD. Another one of the first and second semiconductor layers 11 and 13 may be disposed at the second end EP2 of the light emitting element LD. For example, the first semiconductor layer 11 may be disposed at the first end EP1 of the light emitting element LD, and the second semiconductor layer 13 may be disposed at the second end EP2 of the light emitting element LD.

The light emitting element LD may have a size in a range of a nanometer scale to a micrometer scale. As an example, the light emitting element LD may have a diameter (or width) and/or a length ranging from a nanometer scale to a micrometer scale. However, the size of the light emitting element LD is not limited thereto. The size of the light emitting element LD may be variously changed according to design conditions of various devices (e.g., display device or the like) using a light emitting device (e.g., light emitting element LD) as a light source.

The first semiconductor layer 11 may be a semiconductor layer of a first conductivity type. For example, the first semiconductor layer 11 may include a p-type semiconductor layer. For example, the first semiconductor layer 11 may include a p-type semiconductor layer including at least one semiconductor material of In-AlGaN, GaN, AlGaN, InGaN, and A1N, which is doped with a first conductivity type dopant such as Mg. However, the material constituting the first semiconductor layer 11 is not limited thereto, and various other materials may be used to form the first semiconductor layer 11.

The active layer 12 may be disposed between the first semiconductor layer 11 and the second semiconductor layer 13. The active layer 12 may include any one of a single well structure, a multi-well structure, a single quantum well structure, a multi-quantum well (MQW) structure, a quantum dot structure, and a quantum wire structure, but the disclosure is not limited thereto. The active layer 12 may include at least one of GaN, InGaN, InAlGaN, AlGaN, and AlN. Various other materials may be used to form the active layer 12.

In case that a voltage equal to or greater than a threshold voltage is applied to ends (e.g., both ends) of the light emitting element LD, electron-hole pairs may be combined in the active layer 12, and the light emitting element LD may emit light. The light emission of the light emitting element LD may be controlled using this principle (e.g., combination of electron-hole pairs), the light emitting element LD may be used as a light source of various light emitting devices including pixels of a display device.

The second semiconductor layer 13 may be disposed on the active layer 12, and may include a semiconductor layer of a different type from that of the first semiconductor layer 11. The second semiconductor layer 13 may include an n-type semiconductor layer. For example, the second semiconductor layer 13 may include an n-type semiconductor layer including at least one semiconductor material of InAlGaN, GaN, AlGaN, InGaN, and AlN, which is doped with a second conductivity type dopant such as Si, Ge, Sn, or the like. However, the material constituting the second semiconductor layer 13 is not limited thereto, and various other materials may be used to form the second semiconductor layer 13.

An insulating layer 14 may be provided on a surface (e.g., outer surface) of the light emitting element LD. The insulating layer 14 may be disposed (e.g., directly disposed) on surfaces of the first semiconductor layer 11, the active layer 12, and/or the second semiconductor layer 13. The insulating layer 14 may expose the first and second ends EP1 and EP2 of the light emitting element LD having different polarities from each other. According to an embodiment, the insulating layer 14 may expose side portions of the first semiconductor layer 11 and/or the second semiconductor layer 13 adjacent to the first and second ends EP1 and EP2 of the light emitting element LD.

The insulating layer 14 may prevent an electrical short circuit that may occur in case that the active layer 12 contacts a conductive material other than the first and second semiconductor layers 11 and 13. For example, the active layer 12 may only contact the first and second semiconductor layers 11 and 13 by the insulating layer 14. The insulating layer 14 may minimize surface defects of light emitting elements LD to improve the lifespan and luminous efficiency of the light emitting elements LD.

The insulating layer 14 may include at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx). For example, the insulating layer 14 may be composed of a double layer, and each layer constituting the double layer may include different materials from each other. For example, the insulating layer 14 may be composed of a double layer made of aluminum oxide (AlOx) and silicon oxide (SiOx), but the disclosure is not limited thereto. In some embodiments, the insulating layer 14 may be omitted.

The light emitting elements LD may have different diameters for each area. For example, in the light emitting elements LD, diameters of the first end EP1 and the second end EP2 may be different from each other. The light emitting elements LD may have a cylindrical shape in which a diameter of the first end EP1 is greater than a diameter of the second end EP2. For example, as shown in FIGS. 1 and 2, the diameters of the light emitting elements LD may gradually decrease from the first end EP1 to the second end EP2.

FIG. 3 is a schematic perspective view illustrating a light emitting element according to another embodiment. FIG. 4 is a schematic cross-sectional view illustrating the light emitting element according to another embodiment.

Referring to FIGS. 3 and 4, the light emitting elements LD' may have a shape in which a cylinder having a first diameter and a cylinder having a second diameter smaller than the first diameter are combined. For example, the light emitting element LD may include a first semiconductor layer 11′, an active layer 12′, and/or a second semiconductor layer 13′, which have different cross-sections from those shown in FIGS. 1 and 2. The light emitting element LD' may have a first end EP1′ and a second end EP2′, which have same sizes from those shown in FIGS. 1 and 2. However, the shape of the light emitting elements LD is not limited to the shapes shown in FIGS. 1 to 4, and may be variously changed within a range having different diameters for each area.

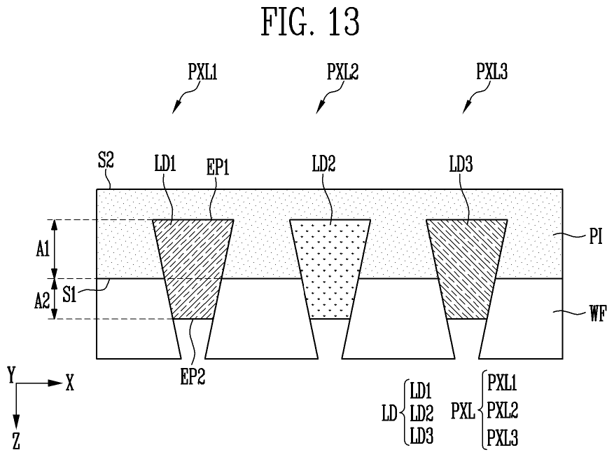

As described above, in case that the light emitting elements LD have different diameters for each area, an area of the light emitting elements LD having a diameter may be assembled or fixed on a wafer or the like, and transferred to a base layer. A detailed description thereof is provided below with reference to FIGS. 12 to 16.

A light emitting device including the above-described light emitting element LD (or light emitting element LD') may be used in various types of devices requiring a light source, including the display device. For example, the light emitting elements LD may be disposed in each pixel of the display panel, and the light emitting elements LD may be used as light sources of each pixel. However, the field to which the light emitting element LD is applied is not limited to the above-described example. For example, the light emitting element LD may also be used in other types of devices that require a light source, such as a lighting device.

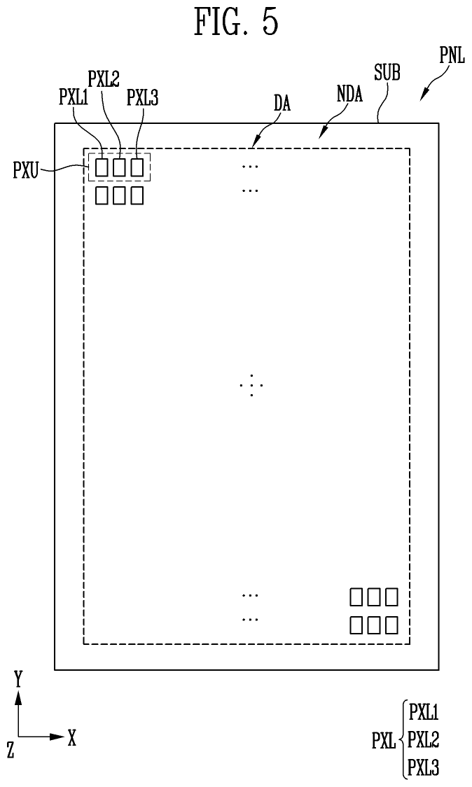

FIG. 5 is a schematic plan view illustrating a display device according to an embodiment.

FIG. 5 shows the display device (e.g., display panel PNL provided in display device) as an example of an electronic device that may use the light emitting element LD (or light emitting element LD') described in the embodiments of FIGS. 1 to 4 as a light source.

For convenience of description, FIG. 5 schematically shows a structure of the display panel PNL centered on a display area DA. However, according to an embodiment, at least one driving circuit part (e.g., at least one of scan driver and data driver), wirings, and/or pads (not shown) may be further disposed on the display panel PNL.

Referring to FIG. 5, the display panel PNL and a substrate SUB for forming the display panel PNL may include the display area DA for displaying an image and a non-display area NDA other than the display area DA. The display area DA may constitute a screen on which an image is displayed, and the non-display area NDA may be an area other than the display area DA. For example, the display area DA may be a portion of the screen, and the non-display area NDA may be a remaining portion of the screen.

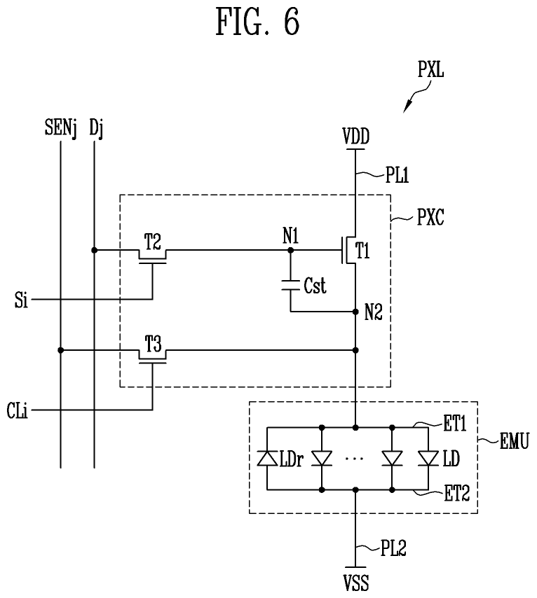

The substrate SUB may be a driving substrate including circuit elements including transistors. The transistors may constitute a pixel circuit PXC (e.g., refer to FIG. 6) of each pixel PXL.

A pixel part PXU may be disposed in the display area DA. The pixel part PXU may include a first pixel PXL1, a second pixel PXL2, and/or a third pixel PXL3. In case that at least one pixel among the first pixel PXL1, the second pixel PXL2, and the third pixel PXL3 or two or more of the pixels PXL1, PLX2, and PXL3 may be generically referred to as “pixel PXL” or “pixels PXL”.

The pixels PXL may be regularly arranged according to a stripe or PENTILE™ arrangement structure. However, the arrangement structure of the pixels PXL is not limited thereto, and the pixels PXL may be arranged in the display area DA in various structures and/or methods.

According to an embodiment, two or more types of pixels PXL emitting light of different colors may be disposed in the display area DA. For example, first pixels PXL1 emitting light of a first color, second pixels PXL2 emitting light of a second color, and third pixels PXL3 emitting light of a third color may be arranged in the display area DA. The first to third pixels PXL1, PXL2, and PXL3 disposed adjacent to each other may constitute each pixel part PXU capable of emitting light of various colors. For example, each of the first to third pixels PXL1, PXL2, and PXL3 may be a pixel emitting light of each of the colors (e.g., first, second, and third colors). According to an embodiment, the first pixel PXL1 may be a red pixel emitting red light, the second pixel PXL2 may be a green pixel emitting green light, and the third pixel PXL3 may be a blue pixel emitting blue light, but the disclosure is not limited thereto.

In an embodiment, the first pixel PXL1, the second pixel PXL2, and the third pixel PXL3 may include light emitting elements emitting light of a same color, color conversion layers and/or color filters having different colors and disposed on each light emitting element. Thus, the first pixel PXL1, the second pixel PXL2, and the third pixel PXL3 may emit light of the first color, light of the second color, and light of the third color, respectively. In another embodiment, the first pixel PXL1, the second pixel PXL2, and the third pixel PXL3 may include a light emitting element of the first color, a light emitting element of the second color, and a light emitting element of the third color as light sources, and emit the light of the first color, the light of the second color, and the light of the third color, respectively. However, the color, type, and/or number of the pixels PXL constituting the pixel part PXU is not limited thereto. For example, the color of the light emitted by each pixel PXL may be variously changed.

The pixel PXL may include at least one light source driven by a control signal (e.g., scan signal and data signal) and/or a power source (e.g., first power source and second power source). In an embodiment, the light source may include at least one light emitting element LD (or light emitting element LD') according to any one of the embodiments of FIGS. 1 to 4. For example, the light source may include ultra-small columnar light emitting elements LD having a size in a range of a nanometer scale to a micrometer scale. However, the disclosure is not limited thereto, and various types of light emitting elements LD may be used as the light source of the pixel PXL.

In an embodiment, each pixel PXL may be composed of an active pixel. However, the types, structures, and/or driving methods of the pixels PXL applicable to the display device are not limited thereto. For example, each pixel PXL may be composed of a pixel of a passive or active type light emitting display device having various structures and/or driving methods.

FIG. 6 is a schematic diagram of an equivalent circuit illustrating a pixel according to an embodiment.

According to an embodiment, a pixel shown in FIG. 6 may be any one of the first pixel PXL1, the second pixel PXL2, and the third pixel PXL3 provided in the display panel PNL of FIG. 5. The first pixel PXL1, the second pixel PXL2, and the third pixel PXL3 (e.g., refer to FIG. 5) may have substantially the same or similar structure to each other.

Referring to FIG. 6, a pixel PXL may include a light emitting part EMU (e.g., refer to FIG. 6) that generates light having a luminance corresponding to a data signal. The pixel PXL may selectively further include a pixel circuit PXC for driving the light emitting part EMU.

According to an embodiment, the light emitting part EMU (e.g., refer to FIG. 6) may include light emitting elements LD electrically connected in parallel between a first power source line PL1 and a second power source line PL2. A voltage of a first driving power source VDD may be applied to the first power source line PL1 from the first driving power source VDD. A voltage of a second driving power source VSS may be applied to the second power source line PL2 from the second driving power source VSS. For example, the light emitting part EMU may include a first electrode ET1, a second electrode ET2, and multiple light emitting elements LD. The first electrode ET1 may be electrically connected to the first driving power source VDD via the pixel circuit PXC and the first power source line PL1. The second electrode ET2 may be electrically connected to the second driving power source VSS through the second power source line PL2. The multiple light emitting elements LD may be electrically connected in parallel in a same direction between the first and second electrodes ET1 and ET2. In an embodiment, the first electrode ET1 may be an anode, and the second electrode ET2 may be a cathode.

Each of the light emitting elements LD included in the light emitting part EMU (e.g., refer to FIG. 6) may include an end electrically connected to the first driving power source VDD through the first electrode ET1 and another end electrically connected to the second driving power source VSS through the second electrode ET2. The first driving power source VDD and the second driving power source VSS may have different potentials. For example, the first driving power source VDD may be set as a high potential power source, and the second driving power source VSS may be set as a low potential power source. A potential difference between the first and second driving power sources VDD and VSS may be set to be greater than or equal to a threshold voltage of the light emitting elements LD during an emission period of the pixel PXL.

As described above, each of the light emitting elements LD electrically connected in parallel in a same direction (e.g., forward direction) between the first electrode ET1 and the second electrode ET2 to which voltages are supplied from different power sources may constitute an effective light source.

The light emitting elements LD of the light emitting part EMU (e.g., refer to FIG. 6) may emit light with a luminance corresponding to a driving current supplied through the corresponding pixel circuit PXC. For example, during each frame period, the pixel circuit PXC may supply the driving current corresponding to a grayscale value of the corresponding frame data to the light emitting part EMU. The driving current supplied to the light emitting part EMU may be divided and flow to the light emitting elements LD. Accordingly, the light emitting part EMU may emit the light having the luminance corresponding to the driving current while each light emitting element LD emits light with a luminance corresponding to a current (e.g., divided current) flowing therethrough.

In the above-described embodiment, ends (e.g., both ends) of the light emitting elements LD may be electrically connected in a same direction between the first and second driving power sources VDD and VSS, but the disclosure is not limited thereto. According to an embodiment, the light emitting part EMU (e.g., refer to FIG. 6) may further include at least one ineffective light source (e.g., reverse direction light emitting element LDr) in addition to the light emitting elements LD constituting each effective light source. The reverse direction light emitting element LDr may be electrically connected in parallel between the first and second electrodes ET1 and ET2 together with the light emitting elements LD constituting the effective light sources, but may be electrically connected between the first and second electrodes ET1 and ET2 in an opposite direction to the light emitting elements LD. The reverse direction light emitting element LDr may maintain a deactivated state although a driving voltage (e.g., forward driving voltage) is applied between the first and second electrodes ET1 and ET2. Thus, a current may not substantially flow through the reverse direction light emitting element LDr.

The pixel circuit PXC may be electrically connected to a scan line Si and a data line Dj of the pixel PXL. Also, the pixel circuit PXC may be electrically connected to a control line CLi and a sensing line SENj of the pixel PXL. For example, in case that the pixel PXL is disposed in an i-th row and a j-th column of the display area DA, the pixel circuit PXC of the pixel PXL may be electrically connected to an i-th scan line Si, a j-th data line Dj, an i-th control line CLi, and a j-th sensing line SENj in the display area DA.

The pixel circuit PXC may include first to third transistors T1, T2, and T3 and a storage capacitor Cst.

The first transistor T1 may be electrically connected between the first driving power source VDD and the light emitting part EMU (e.g., refer to FIG. 6) as a driving transistor for controlling the driving current applied to the light emitting part EMU. For example, a first terminal of the first transistor T1 may be electrically connected to the first driving power source VDD through the first power source line PL1. A second terminal of the first transistor T1 may be electrically connected to a second node N2. A gate electrode of the first transistor T1 may be electrically connected to a first node N1. The first transistor T1 may control the amount of the driving current applied from the first driving power source VDD to the light emitting part EMU through the second node N2 according to a voltage applied to the first node N1. In an embodiment, the first terminal of the first transistor T1 may be a drain electrode, and the second terminal of the first transistor T1 may be a source electrode, but the disclosure is not limited thereto. According to an embodiment, the first terminal may be a source electrode and the second terminal may be a drain electrode.

The second transistor T2 may be electrically connected between the data line Dj and the first node N1 as a switching transistor that selects the pixel PXL in response to a scan signal and activates the pixel PXL. A first terminal of the second transistor T2 may be electrically connected to the data line Dj. A second terminal of the second transistor T2 may be electrically connected to the first node N1. A gate electrode of the second transistor T2 may be electrically connected to the scan line Si. The first terminal and the second terminal of the second transistor T2 may be different terminals from each other. For example, in case that the first terminal is a drain electrode, the second terminal may be a source electrode.

The second transistor T2 may be turned on in case that a scan signal of a gate-on voltage (e.g., high level voltage) is supplied from the scan line Si to electrically connect the data line Dj and the first node N1. The first node N1 may be a point at which the second terminal of the second transistor T2 and the gate electrode of the first transistor T1 are electrically connected, and the second transistor T2 may transmit the data signal to the gate electrode of the first transistor T1.

The third transistor T3 may obtain a sensing signal through the sensing line SENj by electrically connecting the first transistor T1 to the sensing line SENj, and may detect characteristics of the pixel PXL including a threshold voltage of the first transistor T1 using the sensing signal. Information on the characteristics of the pixel PXL may be used to convert image data, and a characteristic deviation between the pixels PXL may be compensated by the converted image data. A second terminal of the third transistor T3 may be electrically connected to the second terminal of the first transistor T1. A first terminal of the third transistor T3 may be electrically connected to the sensing line SENj. A gate electrode of the third transistor T3 may be electrically connected to the control line CLi. The first terminal of the third transistor T3 may be electrically connected to an initialization power source. The third transistor T3 may be an initialization transistor capable of initializing the second node N2, and may be turned on in case that a sensing control signal is supplied from the control line CLi to transmit a voltage of the initialization power source to the second node N2. Accordingly, a second storage electrode of the storage capacitor Cst electrically connected to the second node N2 may be initialized.

A first storage electrode of the storage capacitor Cst may be electrically connected to the first node N1, and the second storage electrode of the storage capacitor Cst may be electrically connected to the second node N2. The storage capacitor Cst may be charged with a data voltage corresponding to the data signal supplied to the first node N1 during a frame period. Accordingly, the storage capacitor Cst may store a voltage corresponding to a voltage difference between a voltage of the gate electrode of the first transistor T1 and a voltage of the second node N2.

FIG. 6 shows an embodiment in which all of the light emitting elements LD constituting the light emitting part EMU are electrically connected in parallel, but the disclosure is not limited thereto. According to an embodiment, the light emitting part EMU may be configured to include at least one serial stage including multiple light emitting elements LD, which are electrically connected in parallel. For example, the light emitting part EMU may be configured in a series/parallel mixed structure.

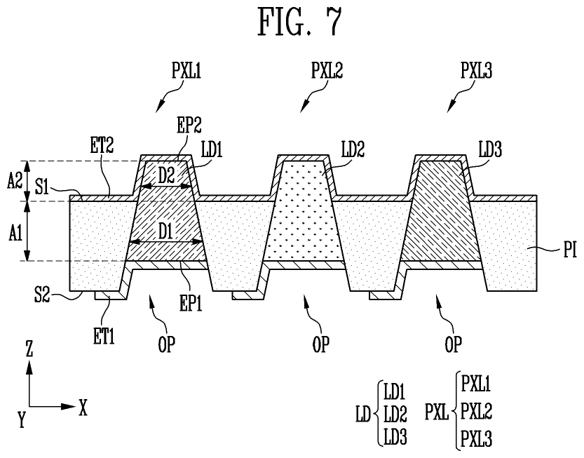

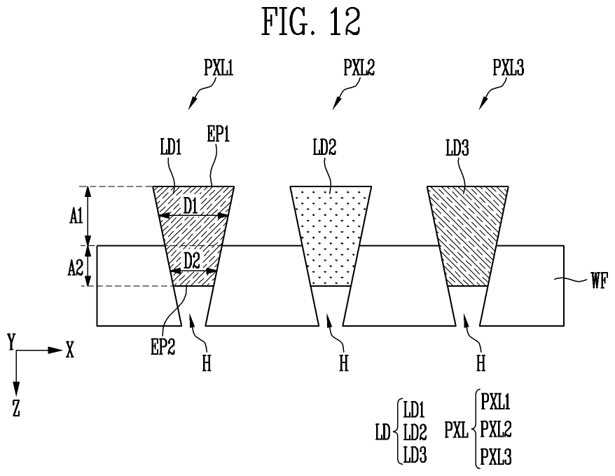

FIGS. 7 to 10 are schematic cross-sectional views of pixels according to an embodiment. FIG. 10 shows a modified embodiment of FIG. 7 in relation to the substrate SUB and the like.

Referring to FIGS. 7 and 10, a pixel PXL and a display device having the pixel PXL may include a base layer PI, light emitting elements LD, a first electrode ET1, and/or a second electrode ET2.

The base layer PI may be made of polyimide having excellent material properties such as flexibility, heat resistance, and insulation (e.g., electrical insulation), but the disclosure is not limited thereto. The base layer PI may include a first surface Si and a second surface S2 facing each other. For example, the first surface Si may correspond to a display surface (or front surface) of a display panel PNL through which light is emitted from the pixel PXL.

Each of first to third pixels PXL1, PXL2, and PXL3 may include light emitting elements LD emitting light of different colors. For example, the first pixel PXL1 may include a first light emitting element LD1 emitting light of a first color. The second pixel PXL2 may include a second light emitting element LD2 emitting light of a second color. The third pixel PXL3 may include a third light emitting element LD3 emitting light of a third color. According to an embodiment, the first light emitting element LD1, the second light emitting element LD2, and the third light emitting device LD3 may be a red light emitting element, a green light emitting element, and a blue light emitting element, respectively, but the disclosure is not limited thereto.

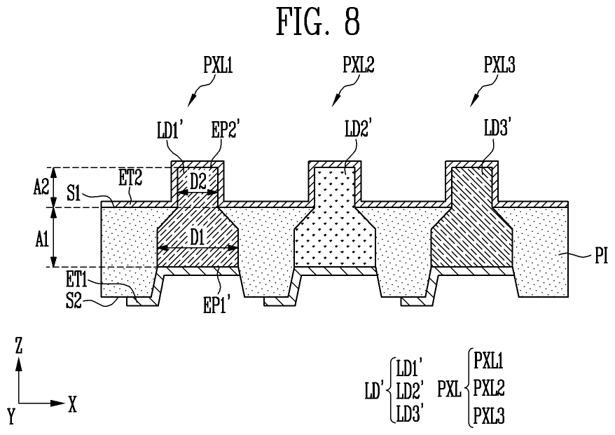

The light emitting elements LD may include a first area A1 disposed inside the base layer PI and a second area A2 other than the first area A1. For example, the first area A1 may be a portion of an area of the light emitting elements LD, and the second area A2 may be a remaining area of the light emitting elements LD. The first area A1 and the second area A2 of the light emitting elements LD may have different diameters. For example, a diameter D1 of the first area A1 of the light emitting elements LD may be greater than a diameter D2 of the second area A2 of the light emitting elements LD. The light emitting elements LD of FIG. 7 may be the light emitting elements LD described with reference to FIGS. 1 and 2. The light emitting elements LD' of FIG. 8 may be the light emitting elements LD' described with reference to FIGS. 3 and 4. For example, the light emitting elements LD' of FIG. 8 may include a first light emitting element LD1′, a second light emitting element LD2′, and a third light emitting LD3′, each of which has a first end EP1′ and a second end EP2′.

The base layer PI may surround the first area A1 of the light emitting elements LD. The base layer PI may surround (e.g., directly surround) an outer surface of the first area A1 of the light emitting elements LD. For example, the base layer PI may be in contact with the first area A1 of the light emitting elements LD. The second area A2 of the light emitting elements LD may protrude from a first surface S1 of the base layer PI.

A second surface S2 of the base layer PI may include an opening OP exposing an end of the first area A1 of the light emitting elements LD. The opening OP of the base layer PI may expose a first end EP1 of the light emitting elements LD.

The first electrode ET1 may be disposed on the first area A1 of the light emitting elements LD. The first electrode ET1 may be disposed on the first end EP1 of the light emitting elements LD. The first electrode ET1 may be disposed on the second surface S2 of the base layer PI. The first electrode ET1 may be disposed (e.g., directly disposed) on the second surface S2 of the base layer PI. The first electrode ET1 may be in contact with the end of the first area A1 of the light emitting elements LD. For example, the first electrode ET1 may be in contact with the first end EP1 of the light emitting elements LD through the opening OP of the base layer PI. For example, a portion of the first electrode ET1 may be disposed on the first ends EP1 (or first area A1) of the light emitting elements LD, and another portion of the first electrode ET1 may be disposed on the second surface S2 of the base layer PI.

The second electrode ET2 may be disposed on the second area A2 of the light emitting elements LD. The second electrode ET2 may be disposed on a second end EP2 of the light emitting elements LD. The second electrode ET2 may be in contact with an end of the second area A2 of the light emitting elements LD. For example, the second electrode ET2 may be in contact with the second end EP2 of the light emitting elements LD. The second electrode ET2 may be disposed on the first surface S1 of the base layer PI. The second electrode ET2 may be disposed (e.g., directly disposed) on the first surface S1 of the base layer PI. For example, a portion of the second electrode ET2 may be disposed on the second ends EP2 (or second area A2) of the light emitting elements LD, and another portion of the second electrode ET2 may be disposed on the first surface of the base layer PI.

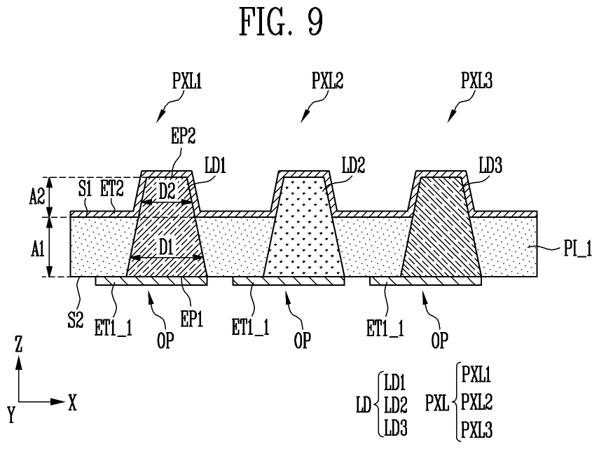

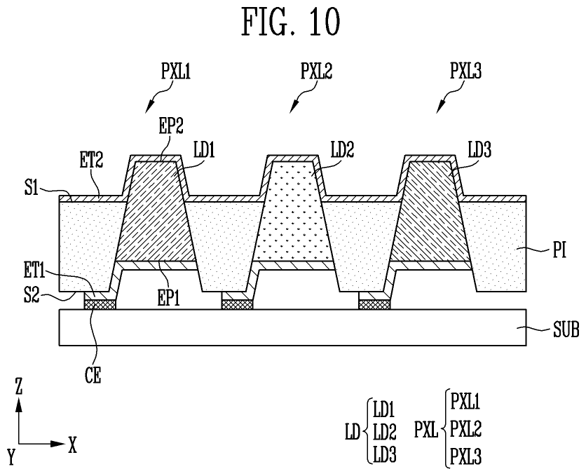

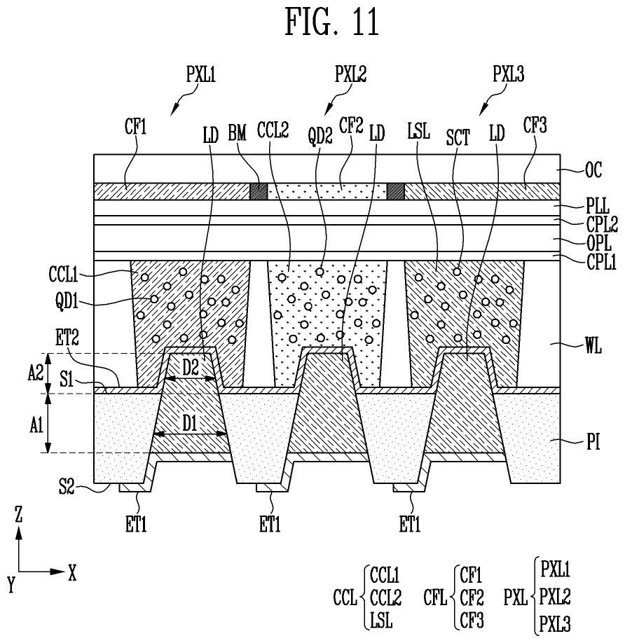

A thickness of the base layer PI in a third direction (e.g., Z-axis direction) may be different from a thickness of the first area A1 of the light emitting elements LD in the third direction (e.g., Z-axis direction). For example, as shown in FIGS. 7 and 8, the thickness of the base layer PI in the third direction (e.g., Z-axis direction) may be greater than the thickness of the first area A1 of the light emitting elements LD in the third direction (e.g., Z-axis direction). For example, in FIGS. 7 and 8, the first end EP1 (or EP1′) of the light emitting elements LD may be recessed upwardly with respect to the second surface S2 of the base layer PI. However, the disclosure is not limited thereto. As shown in FIG. 9, a thickness of a base layer PI_1 in the third direction (e.g., Z-axis direction) may be the same as the thickness of the first area A1 of the light emitting elements LD in the third direction (e.g., Z-axis direction), and a first electrode ET1_1 may be formed under the base layer PI_1 and first ends EP1 of the light emitting elements LD. For example, in FIG. 9, a second surface S2 of the base layer PI_1 and the first ends EP1 of the light emitting elements LD may form a same plane. Herein, the expression “the same (or a same)” may mean substantially the same within a range including manufacturing tolerances and measurement errors.

A substrate SUB may be positioned on the second surface S2 of the base layer PI. The substrate SUB may be a driving substrate including circuit elements and the like including the transistors constituting the pixel circuit PXC (e.g., refer to FIG. 6) of each pixel PXL.

A connection electrode CE may be disposed between the light emitting elements LD and the substrate SUB. The first end EP1 of the light emitting elements LD may be electrically connected to the connection electrode CE provided on the substrate SUB. For example, the first electrode ET1 may be disposed on the first end EP1 of the light emitting elements LD, and the first end EP1 of the light emitting elements LD may be electrically connected to the connection electrode CE provided on the substrate SUB through the first electrode ET1.

As described above, in case that the light emitting elements LD have different diameters for each area and an area of the light emitting elements LD may have a diameter, the light emitting elements LD may be assembled or fixed on a wafer or the like, and readily transferred to the base layer PI having flexibility. For example, the diameter D1 of the first area A1 of the light emitting elements LD may be greater than the diameter D2 of the second area A2 of the light emitting elements LD, and the light emitting elements LD may be readily transferred to the base layer PI having flexibility.

Description of another embodiment is provided below. In the following embodiment, detailed description of the same constituent elements is omitted or simplified.

FIG. 11 is a schematic cross-sectional view illustrating a pixel according to another embodiment.

Referring to FIG. 11, first to third pixels PXL1, PXL2, and PXL3 may include light emitting elements LD emitting light of a same color. For example, the first to third pixels PXL1, PXL2, and PXL3 may include light emitting elements LD emitting light of a third color (e.g., blue light). A color conversion layer CCL may be disposed on at least some of the first to third pixels PXL1, PXL2, and PXL3, and a full-color image may be displayed.

A partition wall or bank WL (hereinafter, referred to as “bank WL”), the color conversion layer CCL, an optical layer OPL, and/or a color filter layer CFL may be disposed on a base layer PI.

The bank WL may be disposed between or at a boundary between adjacent ones of the first to third pixels PXL1, PXL2, and PXL3, and may include an opening overlapping the first to third pixels PXL1, PXL2, and PXL3, respectively, in a plan view. The opening of the bank WL may provide a space in which the color conversion layer CCL may be provided.

The bank WL may include at least one organic material of an acrylic resin, an epoxy resin, a phenolic resin, a polyamide resin, a polyimide resin, a polyester resin, a polyphenylenesulfide resin, and benzocyclobutene (BCB). However, the disclosure is not limited thereto, and the bank WL may include various kinds of inorganic materials including at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx).

According to an embodiment, the bank WL may include at least one light blocking and/or reflective material. Accordingly, light leakage between adjacent pixels PXL may be prevented. For example, the bank WL may include at least one black matrix material and/or color filter material. For example, the bank WL may be formed in a black opaque pattern capable of blocking light transmission. In an embodiment, a reflective film (not shown) or the like may be formed on a surface (e.g., sidewall) of the bank WL to increase the light efficiency (e.g., luminance in front direction) of each pixel PXL.

The color conversion layer CCL may be disposed on the base layer PI including the light emitting elements LD within the opening of the bank WL. The color conversion layer CCL may include a first color conversion layer CCL1 disposed in the first pixel PXL1, a second color conversion layer CCL2 disposed in the second pixel PXL2, and a scattering layer LSL disposed in the third pixel PXL3.

The first color conversion layer CCL1 may include first color conversion particles that convert light of the third color emitted from the light emitting element LD into light of a first color. For example, the first color conversion layer CCL1 may include first quantum dots QD1 dispersed in a matrix material such as a base resin.

In an embodiment, in case that the light emitting element LD is a blue light emitting element emitting blue light and the first pixel PXL1 is a red pixel, the first color conversion layer CCL1 may include first quantum dots QD1 that convert the blue light emitted from the blue light emitting element into red light. The first quantum dots QD1 may absorb the blue light and shift a wavelength according to energy transition to emit the red light. In case that the first pixel PXL1 is a pixel of a different color, the first color conversion layer CCL1 may include first quantum dots QD1 corresponding to the color of the first pixel PXL1.

The second color conversion layer CCL2 may include second color conversion particles that convert light of the third color emitted from the light emitting element LD into light of a second color. For example, the second color conversion layer CCL2 may include second quantum dots QD2 dispersed in a matrix material such as a base resin.

In an embodiment, in case that the light emitting element LD is the blue light emitting element emitting the blue light and the second pixel PXL2 is a green pixel, the second color conversion layer CCL2 may include second quantum dots QD2 that convert the blue light emitted from the blue light emitting element into green light. The second quantum dots QD2 may absorb the blue light and shift a wavelength according to energy transition to emit the green light. In case that the second pixel PXL2 is a pixel of a different color, the second color conversion layer CCL2 may include second quantum dots QD2 corresponding to the color of the second pixel PXL2.

In an embodiment, in case that the blue light having a relatively short wavelength in the visible light region is incident on the first quantum dots QD1 and the second quantum dots QD2, absorption coefficients of the first quantum dots QD1 and the second quantum dots QD2 may be increased. Accordingly, the efficiency of light finally emitted from the first pixel PXL1 and the second pixel PXL2 may be improved, and excellent color reproducibility may be secured. Since the light emitting part EMU (e.g., refer to FIG. 6) of the first to third pixels PXL1, PXL2, and PXL3 may be configured using light emitting elements LD of a same color (e.g., blue light emitting elements), manufacturing efficiency of the display device may be improved.

The scattering layer LSL may be provided to efficiently use light of the third color (or blue light) emitted from the light emitting element LD. For example, in case that the light emitting element LD is the blue light emitting element emitting the blue light and the third pixel PXL3 is a blue pixel, the scattering layer LSL may include at least one type of a scatterer SCT to efficiently use the light emitted from the light emitting element LD.

For example, the scattering layer LSL may include multiple scatterers SCT dispersed in a matrix material such as a base resin. For example, the scattering layer LSL may include the scatterers SCT such as silica, but the material constituting the scatterers SCT is not limited thereto. The scatterers SCT may not be disposed only in the third pixel PXL3, and may be selectively included in the first color conversion layer CCL1 and/or the second color conversion layer CCL2. According to an embodiment, the scatterers SCT may be omitted, and the scattering layer LSL may be made of a transparent polymer.

A first capping layer CPL1 may be disposed on the color conversion layer CCL. The first capping layer CPL1 may be provided over the first to third pixels PXL1, PXL2, and PXL3. The first capping layer CPL1 may cover the color conversion layer CCL. The first capping layer CPL1 may prevent impurities such as moisture or air from penetrating from outside. Thus, the color conversion layer CCL may not be damaged or contaminated by the first capping layer CPL1.

The first capping layer CPL1 may be an inorganic layer, and may include at least one of silicon nitride (SiNx), aluminum nitride (AlNx), titanium nitride (TiNx), silicon oxide (SiOx), aluminum oxide (AlOx), titanium oxide (TiOx), silicon oxycarbide SiOxCy, and silicon oxynitride SiOxNy. However, the disclosure is not limited thereto.

The optical layer OPL may be disposed on the first capping layer CPL1. The optical layer OPL may recycle light provided from the color conversion layer CCL by total reflection to improve light extraction efficiency. Thus, the optical layer OPL may have a relatively low refractive index compared to the color conversion layer CCL. For example, the refractive index of the color conversion layer CCL may be in a range of about 1.6 to about 2.0, and the refractive index of the optical layer OPL may be in a range of about 1.1 to about 1.3.

A second capping layer CPL2 may be disposed on the optical layer OPL. The second capping layer CPL2 may be provided over the first to third pixels PXL1, PXL2, and PXL3. The second capping layer CPL2 may cover the optical layer OPL. The second capping layer CPL2 may prevent impurities such as moisture or air from penetrating from outside. Thus, the optical layer OPL may not be damaged or contaminated by the second capping layer CPL2.

The second capping layer CPL2 may be an inorganic layer, and may include at least one of silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), and silicon oxynitride (SiOxNy). However, the disclosure is not limited thereto.

A planarization layer PLL may be disposed on the second capping layer CPL2. The planarization layer PLL may be provided over the first to third pixels PXL1, PXL2, and PXL3.

The planarization layer PLL may include at least one organic material of an acrylic resin, an epoxy resin, a phenolic resin, a polyamide resin, a polyimide resin, a polyester resin, a polyphenylenesulfide resin, and benzocyclobutene (BCB). However, the disclosure is not limited thereto, and the planarization layer PLL may include various types of inorganic materials including at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx).

The color filter layer CFL may be disposed on the planarization layer PLL. The color filter layer CFL may include color filters CF1, CF2, and CF3 matching the color of each pixel PXL. The color filters CF1, CF2, and CF3 matching the colors of the first to third pixels PXL1, PXL2, and PXL3 may be disposed in the first to third pixels PXL1, PXL2, and PXL3, respectively, and a full-color image may be displayed.

The color filter layer CFL may include a first color filter CF1, a second color filter CF2, and a third color filter CF3. The first color filter CF1 may be disposed in the first pixel PXL1 to selectively transmit light emitted from the first pixel PXL1. The second color filter CF2 may be disposed in the second pixel PXL2 to selectively transmit light emitted from the second pixel PXL2. The third color filter CF3 may be disposed in the third pixel PXL3 to selectively transmit light emitted from the third pixel PXL3.

In an embodiment, the first color filter CF1, the second color filter CF2, and the third color filter CF3 may be a red color filter, a green color filter, and a blue color filter, respectively, but the disclosure is not limited thereto. Any color filter or two types (or more types) of color filters among the first color filter CF1, the second color filter CF2, and the third color filter CF3 may be referred to as “color filter CF” or “color filters CF”.

The first color filter CF1 may overlap the light emitting element LD of the first pixel PXL1 and the first color conversion layer CCL1 in a third direction (e.g., Z-axis direction). The first color filter CF1 may include a color filter material that selectively transmits light of the first color (or red). For example, in case that the first pixel PXL1 is a red pixel, the first color filter CF1 may include a red color filter material.

The second color filter CF2 may overlap the light emitting element LD of the second pixel PXL2 and the second color conversion layer CCL2 in the third direction (e.g., Z-axis direction). The second color filter CF2 may include a color filter material that selectively transmits light of the second color (or green). For example, in case that the second pixel PXL2 is a green pixel, the second color filter CF2 may include a green color filter material.

The third color filter CF3 may overlap the light emitting element LD of the third pixel PXL3 and the scattering layer LSL in the third direction (e.g., Z-axis direction). The third color filter CF3 may include a color filter material that selectively transmits light of the third color (or blue). For example, in case that the third pixel PXL3 is a blue pixel, the third color filter CF3 may include a blue color filter material.

According to an embodiment, a light blocking layer BM may be further disposed between adjacent ones of the first to third color filters CF 1, CF2, and CF3. In case that the light blocking layer BM is formed between the adjacent ones of the first to third color filters CF 1, CF2, and CF3, color mixing defects visually recognized from the front or side of the display device may be prevented. The material of the light blocking layer BM is not limited, and may be composed of various light blocking materials. For example, the light blocking layer BM may be implemented by stacking the first to third color filters CF1, CF2, and CF3.

An overcoat layer OC may be disposed on the color filter layer CFL. The overcoat layer OC may be provided over the first to third pixels PXL1, PXL2, and PXL3. The overcoat layer OC may cover a lower member including the color filter layer CFL. The overcoat layer OC may prevent moisture or air from penetrating into the above-described lower member. The overcoat layer OC may protect the above-described lower member (e.g., color filter layer CFL) from foreign substances such as dust.

The overcoat layer OC may include at least one organic material of an acrylic resin, an epoxy resin, a phenolic resin, a polyamide resin, a polyimide resin, a polyester resin, a polyphenylenesulfide resin, and benzocyclobutene (BCB). However, the disclosure is not limited thereto, and the overcoat layer OC may include various types of inorganic materials including at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx).

Description of a method of manufacturing the display device according to the above-described embodiments is provided below.

FIGS. 12 to 16 are schematic cross-sectional views illustrating a method of manufacturing a display device according to an embodiment in each process step. FIGS. 12 to 16 are schematic cross-sectional views for explaining a method of manufacturing the display device based on FIG. 7. Detailed description of the same constituent elements is omitted.

Referring to FIG. 12, light emitting elements LD may be assembled and fixed to a wafer WF in which holes H are formed. A silicon wafer may be used as the wafer WF, but the disclosure is not limited thereto. The light emitting elements LD may be integrated on the wafer WF, and transferred to a base layer PI, which is described below, to realize a high-resolution display device.

As described above, the light emitting elements LD may include a first area A1 and a second area A2 having different diameters. A diameter D1 of the first area A1 of the light emitting elements LD may be greater than a diameter D2 of the second area A2 of the light emitting elements LD.

The shape of each hole H of the wafer WF may correspond to the shape of the second area A2 of the light emitting elements LD. For example, a diameter of the hole H of the wafer WF may be the same as the diameter D2 of the second area A2 of the light emitting elements LD. Accordingly, the second area A2 of the light emitting elements LD may be assembled and fixed in the hole H of the wafer WF. The diameter D1 of the first area A1 of the light emitting elements LD may be greater than the diameter of the hole H of the wafer WF. Accordingly, the first area A1 of the light emitting elements LD may protrude from a surface (e.g., upper surface) of the wafer WF.

Light emitting elements LD emitting light of different colors may be assembled or fixed to each of first to third pixels PXL1, PXL2, and PXL3. For example, a first light emitting element LD1 emitting light of a first color may be assembled or fixed to the first pixel PXL1. A second light emitting element LD2 emitting light of a second color may be assembled or fixed to the second pixel PXL2. A third light emitting element LD3 emitting light of a third color may be assembled or fixed to the third pixel PXL3. According to an embodiment, the first light emitting element LD1, the second light emitting element LD2, and the third light emitting element LD3 may be a red light emitting element, a green light emitting element, and a blue light emitting element, respectively, but the disclosure is not limited thereto.

According to an embodiment, as described with reference to FIG. 11, light emitting elements LD emitting light of a same color may be assembled or fixed to each of the first to third pixels PXL1, PXL2, and PXL3. For example, light emitting elements LD emitting light of the third color (e.g., blue light) may be assembled or fixed to the first to third pixels PXL1, PXL2, and PXL3.

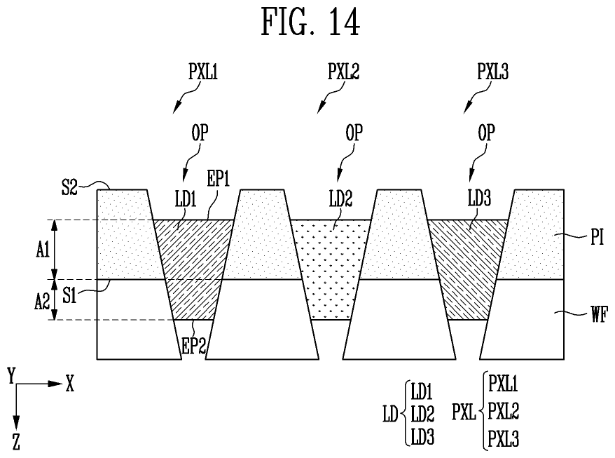

Referring to FIG. 13, a base layer PI may be formed on the wafer WF. The base layer PI may be formed by coating polyimide or the like on the surface (e.g., upper surface) of the wafer WF. The base layer PI may be formed in (or may cover) the first area A1 of the light emitting elements LD protruding from the wafer WF. The base layer PI may be coated (e.g., directly coated) on the first area A1 of the light emitting elements LD to be in contact with the first area A1 of the light emitting elements LD.

A thickness of the base layer PI in a third direction (e.g., Z-axis direction) may be different from a thickness of the first area A1 of the light emitting elements LD in the third direction (e.g., Z-axis direction). For example, the thickness of the base layer PI in the third direction (e.g., Z-axis direction) may be greater than the thickness of the first area A1 of the light emitting elements LD in the third direction (e.g., Z-axis direction). However, the disclosure is not limited thereto. As described with reference to FIG. 9, the thickness of the base layer PI in the third direction (e.g., Z-axis direction) may be the same as the thickness of the first area A1 of the light emitting elements LD in the third direction (e.g., Z-axis direction).

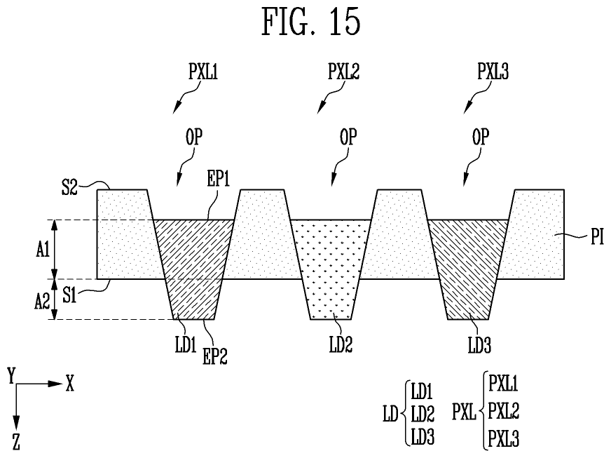

Referring to FIG. 14, an opening OP may be formed by etching the base layer PI. A second surface S2 of the base layer PI may be at least partially etched to form the opening OP of the base layer PI. The opening OP of the base layer PI may expose an end (e.g., first end EP1) of the first area A1 of the light emitting elements LD. The opening OP of the base layer PI may expose the first end EP1 of the light emitting elements LD.

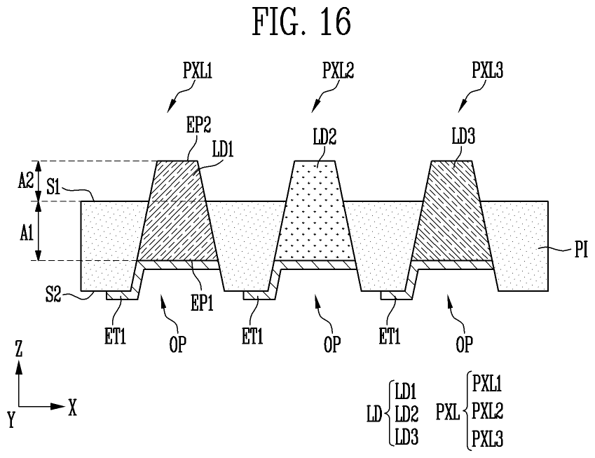

Referring to FIG. 15, the base layer PI and the light emitting elements LD may be separated from the wafer WF (e.g., refer to FIG. 14). The second area A2 of the light emitting elements LD may be separated from the wafer WF and exposed. For example, the second area A2 of the light emitting elements LD may protrude from a first surface S1 of the base layer PI. According to an embodiment, in order to reduce manufacturing cost, the separated wafer WF may be reused in the step of assembling or fixing the light emitting elements LD, which is described with reference to FIG. 12.

Referring to FIG. 16, a first electrode ET1 may be formed on the first end EP1 of the light emitting elements LD. The first electrode ET1 may be formed on the end (e.g., first end EP1) of the first area A1 of the light emitting elements LD, which is exposed by the opening OP of the base layer PI, and be in contact with the end of the first area A1 of the light emitting elements LD. Also, the first electrode ET1 may be disposed on the second surface S2 of the base layer PI. The first electrode ET1 may be disposed (e.g., directly disposed) on the second surface S2 of the base layer PI. For example, the first electrode ET1 may be formed on the first ends EP1 of the light emitting elements SL and the second surface S2 of the base layer PL.

A second electrode ET2 may be formed on a second end EP2 of the light emitting elements LD, and the display device shown in FIG. 7 may be completed. The second electrode ET2 (e.g., refer to FIG. 7) may be formed in the second area A2 of the light emitting elements LD protruding from the first surface S1 of the base layer PI, and be in contact with the second area A2 of the light emitting elements LD. Also, the second electrode ET2 may be disposed on the first surface S1 of the base layer PI. The second electrode ET2 may be disposed (e.g., directly disposed) on the first surface S1 of the base layer PI. For example, the second electrode ET2 may be disposed on the second electrodes EP2 of the light emitting elements LD and the first surface S1 of the base layer PI.

According to the above-described embodiments, the light emitting elements LD including the first area A1 and the second area A2 having different diameters may be integrated on the wafer WF, and transferred to the base layer PI to realize a high-resolution display device.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
light emitting elements each including a first area and a second area having different diameters; and
a base layer surrounding the first area of the light emitting elements and contacting the first area of each of the light emitting elements,
wherein the second area of each of the light emitting elements protrudes from a first surface of the base layer.

2. The display device of claim 1, wherein a diameter of the first area of each of the light emitting elements is greater than a diameter of the second area of each of the light emitting elements.

3. The display device of claim 2, wherein each of the light emitting elements includes:
a first semiconductor layer;
a second semiconductor layer; and
an active layer disposed between the first semiconductor layer and the second semiconductor layer.

4. The display device of claim 3, further comprising:
a first electrode disposed on the first area of each of the light emitting elements.

5. The display device of claim 4, wherein the base layer includes an opening exposing an end of the first area of each of the light emitting elements.

6. The display device of claim 5, wherein the first electrode electrically contacts the end of the first area of each of the light emitting elements through the opening of the base layer.

7. The display device of claim 6, wherein the first electrode is disposed directly on a second surface of the base layer.

8. The display device of claim 7, further comprising:
a second electrode disposed on the second area of each of the light emitting elements.

9. The display device of claim 8, wherein the second electrode is disposed directly on the first surface of the base layer.

10. The display device of claim 9, wherein a thickness of the base layer is greater than a thickness of the first area of each of the light emitting elements.

11. The display device of claim 9, wherein a thickness of the base layer is substantially equal to a thickness of the first area of each of the light emitting elements.

12. The display device of claim 11, wherein the light emitting elements include:
a first light emitting element emitting light of a first color;
a second light emitting element emitting light of a second color; and
a third light emitting element emitting light of a third color.

13. The display device of claim 12, further comprising:
a color conversion layer disposed on the light emitting elements.

14. The display device of claim 13, further comprising:
a color filter layer disposed on the color conversion layer.

15. A method of manufacturing a display device comprising:
preparing light emitting elements each including a first area and a second area having different diameters;
fixing the second area of each of the light emitting elements to a wafer;
forming a base layer on the first area of each of the light emitting elements protruding from the wafer; and
separating the base layer and the second area of each of the light emitting elements from the wafer.

16. The method of claim 15, wherein a diameter of the first area of each of the light emitting elements is greater than a diameter of the second area of each of the light emitting elements.

17. The method of claim 16, wherein a thickness of the base layer is greater than a thickness of the first area of each of the light emitting elements.

18. The method of claim 17, further comprising:
etching the base layer to form an opening exposing an end of the first area of each of the light emitting elements.

19. The method of claim 18, further comprising:
forming a first electrode on the end of the first area of each of the light emitting elements exposed by the opening of the base layer.

20. The method of claim 19, further comprising:
forming a second electrode on the second area of each of the light emitting elements separated from the wafer and exposed.
